(19) United States
(12) Patent Application Publication
(10) Pub. No.: US 2025/0113598 A1
(43) Pub. Date: Apr. 3, 2025

(54) MULTI-THRESHOLD SCHEME USING DUAL DIPOLE PATTERNING IN COMPLEMENTARY TRANSISTOR DIELECTRICS

(71) Applicant: Intel Corporation, Santa Clara, CA (US)

(72) Inventors: Dan Lavric, Portland, OR (US); Jubin Nathawat, Hillsboro, OR (US); Orb Acton, Portland, OR (US); Michal Mleczko, Portland, OR (US); Owen Loh, Portland, OR (US); Michael L. Hattendorf, Portland, OR (US)

(73) Assignee: Intel Corporation, Santa Clara, CA (US)

(21) Appl. No.: 18/375,314

(22) Filed: Sep. 29, 2023

(51) Int. Cl. H01L 27/092; H01L 21/8238; H01L 29/20; H01L 29/423; H01L 29/51

(52) U.S. Cl. CPC H10D 84/85; H10D 62/8503; H10D 64/514; H10D 64/691; H10D 84/0167; H10D 84/017; H10D 84/0181; H10D 84/038

(57) ABSTRACT

An integrated circuit (IC) device includes n- and p-type transistors with and without threshold voltage shifts using a common dopant material in a gate dielectric. The IC device includes at least four threshold voltage for each of n- and p-type transistors. Besides volumeless doping of gate dielectrics, work function metals are used in both n- and p-type transistors. A single dipole dopant may be concurrently introduced into and through similar gate dielectrics in both n- and p-type transistors to achieve consistent threshold voltage shifts with minimal process variation.

### BACKGROUND

As device dimensions and performance requirements tighten, new techniques, structures, and materials are needed to increase performance, provide design flexibility, and improve reliability.

The ability to tune transistor threshold voltages and the availability of transistors with various threshold voltages enable the design and manufacture of devices with optimized characteristics. For example, transistors with lower threshold voltages can be deployed in critical paths where fast switching is desired, and transistors with higher threshold voltages can be deployed where low leakage is a higher priority. However, as new processes, design constraints, and performance and reliability demands are introduced, materials, structures, and techniques are needed to provide transistors with desired ranges of multiple threshold voltages.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate cross-sectional profile views of transistors with a range of threshold voltages in the same integrated circuit (IC) device, in accordance with some embodiments;

FIGS. 2A, 2B, 2C, and 2D illustrate cross-sectional profile views of transistors with a range of threshold voltages in the same IC device, in accordance with some embodiments;

FIG. 3 is a plot showing relative threshold voltages of various transistors, in accordance with some embodiments;

FIGS. 4A and 4B illustrate plan and cross-sectional profile views of an example IC device with transistors of complementary conductivity types in a multi-threshold scheme, in accordance with some embodiments;

FIG. 5 is a flow chart of methods for forming transistors with multiple threshold voltages, including by doping gate insulators and shifting threshold voltages, in accordance with some embodiments;

FIG. 6 illustrates a diagram of an example data server machine employing an IC device having both doped gate insulators and multiple threshold voltages in both n- and p-type transistors, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices having transistors of complementary conductivities by providing a spread of threshold voltages (Vₜ) for transistors of both conductivities. For example, metal-oxide-semiconductor (MOS) transistors may be of n- or p-type conductivities, and complementary MOS (CMOS) field-effect transistors (FETs) integrate both conductivity types in paired devices. The current disclosure describes a multiple-threshold CMOS scheme with a range of Vₜ for transistors of both conductivity types. The scheme utilizes “volumeless” threshold shifting in transistors of both conductivity types, as well as one or more layers of work-function metals. This enables the scheme to provide an advantageously broad span of Vₜ with beneficially fine resolution between the Vₜ steps in the span.

Different applications, deployments, etc., of transistor may have different optimal Vₜ. A lower Vₜ (and a correspondingly faster switching time) may be highly valuable in critical paths with tight delay constraints. A higher Vₜ (and a correspondingly lower leakage current) may be otherwise by more highly valued. An advantageous scheme provides the ability to tune a transistor Vₜ for a given application. An optimal scheme provides transistors with various Vₜ tuned for the use in particular applications, including transistors with intermediate Vₜ, e.g., for applications that require a balancing of various characteristics (such as a sufficiently low leakage current while still providing sufficiently fast switching).

The threshold voltage Vₜ of a FET is the minimum gate bias (e.g., relative to a voltage on the source terminal of the transistor; gate-to-source voltage (V_{GS})) needed for conduction between the source and drain terminals of the FET. The threshold for conduction (and so the threshold voltage Vₜ) may be defined by a certain threshold drive current. Characteristics that affect the relationship between drive current and gate bias may therefore affect the Vₜ. For a given gate bias, drive current may be higher (e.g., be increased) for a transistor with a gate dielectric having higher permittivity. A transistor with a gate dielectric having higher permittivity may provide a given drive current with a lower gate bias. It follows that a FET with a high-permittivity (“high-K”) gate dielectric with have a lower Vₜ than a FET with a low-permittivity (“low-K”) gate dielectric, and a material or technique that tunes a permittivity of a transistor gate dielectric may tune the Vₜ of the transistor.

The disclosed multi-threshold scheme employs dopants, such as dipole dopants, to adjust a FET Vₜ by adjusting the permittivity of the transistor gate dielectric. The permittivity of a dielectric material is a measure of the material's polarizability in response to an applied electric field, which is proportional to the material's ability to store energy in response to the electric field. The material's polarizability is the tendency or ability of the material, when subjected to the applied field, to develop an electric dipole moment in proportion to that applied field. Dipole dopants increase a dielectric material's polarizability by creating or strengthening local dipole moments in the material. These dipole moments may be due to the orientation (e.g., alignment) of polar molecules or displacement of an electron cloud from a corresponding nucleus, or the displacement or distortion of ions within the material. The deployment of dopants in gate dielectrics to tune permittivities is a volumeless technique that efficiently adjusts a FET Vₜ without increasing the space (e.g., volume) occupied by a gate structure (e.g., dielectric plus electrode).

A disclosed multi-threshold scheme also employs work function metals (WFM) in transistor gate electrodes. WFMs shift FET Vₜ and conduction by aiding or inhibiting the formation of the gate field (relative to other metals) due to the influence of the WFM on the electrostatic potential at a surface of the WFM, e.g., at an interface with another material, such as the gate dielectric. Different WFMs and/or different thicknesses of WFMs may be used to provide different Vₜ. Added layers of WFMs, or WFM layers with increased thicknesses, may increase the volume occupied by a gate electrode, but may enable further Vₜ shifts in transistors with sufficient volume (e.g., around channel regions at sufficiently large pitches). WFMs may also provide improved reliability relative to structures without properly selected WFMs.

Embodiments described herein utilize both dipole dopants and WFMs in both n- and p-type transistors, e.g., NMOS and PMOS FETs. These multi-threshold schemes allow for broad ranges of Vₜ and for fine resolution between Vₜ steps. The disclosed gate stacks improve device reliability by reducing processing operations and minimizing exposure to unnecessary etches. The disclosed gate stacks have been shown to improve device reliability, e.g., by minimizing threshold voltage drift over device lifetime (and so minimizing consequent decreases in drain current and transconductance).

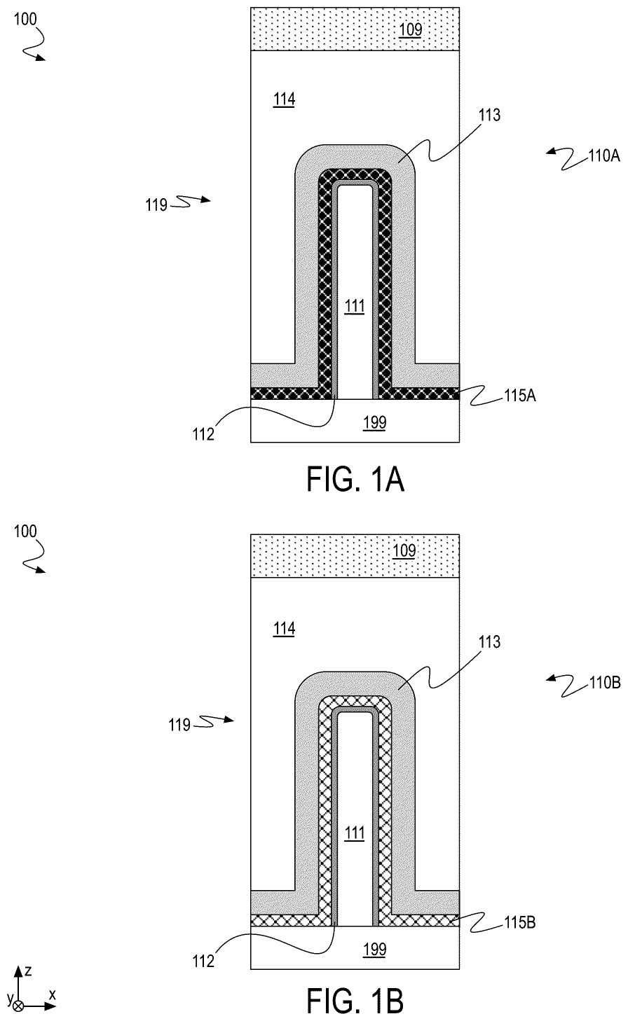

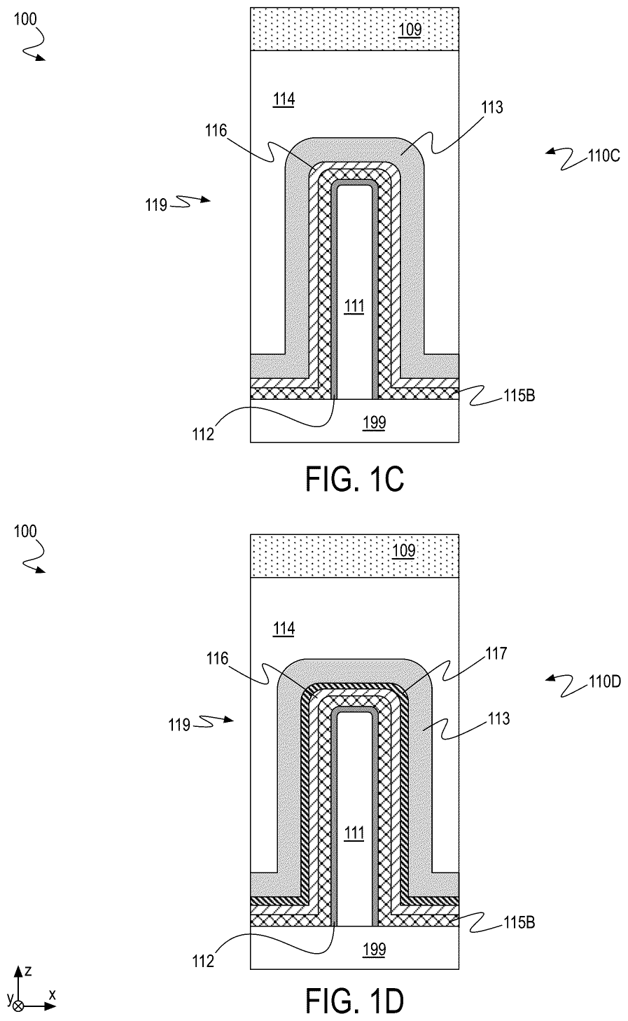

FIGS. 1A, 1B, 1C, and 1D illustrate cross-sectional profile views of transistors 110 with a range of threshold voltages Vₜ in the same IC device 100, in accordance with some embodiments. FIG. 1A shows transistor 110A on a substrate 199 in device 100, and FIG. 1B shows a transistor 110B also on substrate 199 in device 100. Transistors 110A, 110B have similar structures and each include a gate structure 119 over a semiconductor fin, including a channel region 111 within the fin. Gate structure 119 includes interface layer 112 over region 111, as well as gate insulator 115 over layer 112. Gate structure 119 also includes metals 113, 114. A layer of work-function metal 113 is over gate insulator 115 (e.g., insulator 115A in transistor 110A, and insulator 115B in transistor 1101B). In the cross-sectional views of FIGS. 1A and 1B, bulk metal 114 is over the layer of WFM 113. Gate structure 119 may continue beyond the views of FIGS. 1A and 1B, extending in both x directions, and bulk metal 114 may be within a conformal layer of metal 113. WFM 113 may be conformal to adjacent structures (such as spacer materials between gate structure 119 and nearby source or drain structures or other gate structures). In this way, WFM 113 may be a liner metal around fill or bulk metal 114. Insulator 109 is over transistor 110A.

Transistor 110B in FIG. 1B may have the same structure as transistor 110A of FIG. 1A except that gate insulator 115B over interface layer 112 lacks a dopant material included within gate insulator 115A. The presence of the dopant material in gate insulator 115A may have the effect of a shifted Vₜ of transistor 110A, such that threshold voltages V_{t1A}, V_{t1B} of transistors 110A, 110B, respectively may be different despite transistors 110A, 110B having otherwise identical compositions and structures.

Gate insulator 115 (e.g., gate insulator 115A, 115B in transistor 110A, 110B, respectively) provides electrical insulation between channel region 111 and an electrode of gate structure 119. Gate insulator 115 enables electrostatic control of the conduction of channel region 111. Gate insulators 115 may have more than one layer. Gate insulators 115 may be of any suitable material(s). The one or more layers of gate insulators 115 may include a silicon oxide (e.g., silicon dioxide, SiO₂), a silicon oxynitride, etc.

Gate insulators 115 may include high-K dielectric materials (for example, materials having a dielectric constant over 7), e.g., to improve transconductance. For example, a high-K (or high-dielectric constant) insulator 115 may result in increased conductance of transistor 110 (through channel region 111) for a given bias at gate structure 119 or a lower required gate bias for a same conductance. A high-K dielectric material may include one or more of various elements, such as silicon, oxygen, and/or one or more of various metals (e.g., hafnium, titanium, tantalum, lanthanum, aluminum, zirconium, barium, strontium, yttrium, lead, scandium, niobium, and zinc). In many embodiments, gate insulators 115 include an oxide of hafnium (such as hafnium oxide, HfO₂). Other examples of high-K materials that may be used in gate insulators 115 include, but are not limited to, hafnium silicon oxide, lanthanum oxide, hafnium lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, etc. Gate insulators 115 may include other compositions, such as other metal oxides.

Gate insulators 115A, 115B may have the same structure and composition, except that gate insulator 115A includes a dopant material and a correspondingly shifted Vₜ. For example, both gate insulators 115 may be a layer of a first metal oxide, and gate insulator 115A may additionally include a second metal (e.g., in a second metal oxide) as a dopant that gate insulator 115B lacks. The dopant may be an n- or p-type dipole dopant. In some embodiments, gate insulator 115A includes a Vₜ-shifting n-dipole dopant that reduces the magnitude of an NMOS transistor 110A threshold voltage V_{t1A} to be less than the magnitude of an NMOS transistor 110B threshold voltage V_{t1B} (with transistor 110B having gate insulator 115B absent an n-dipole dopant). In some embodiments, gate insulator 115A includes a Vₜ-shifting p-dipole dopant that reduces the magnitude of a PMOS transistor 110A threshold voltage V_{t1A} to be less than the magnitude of an PMOS transistor 110B threshold voltage V_{t1B} (with transistor 110B having gate insulator 115B absent a p-dipole dopant). In some embodiments, gate insulator 115A includes a Vₜ-shifting p-dipole dopant that increases the magnitude of an NMOS transistor 110A threshold voltage V_{t1A} to be greater than the magnitude of an NMOS transistor 110B threshold voltage V_{t1B} (with transistor 110B having gate insulator 115B absent a p-dipole dopant).

The presence of a dopant material in gate insulator 115A may have the effect of a shifted Vₜ of transistor 110A, and the shift of threshold voltage V_{t1A} from that of threshold voltage V_{t1B} of transistor 110B with undoped gate insulator 115B may correspond to the dopant concentration in gate insulator 115A. The dopant may be distributed throughout insulator 115A, but the distribution may be such that more dopant is present, e.g., at or nearer interface layer 112, or opposite interface layer 112, which may influence the shift between threshold voltages V_{t1A}, V_{t1B}. A transistor 110A with a greater amount of the dopant material in gate insulator 115A may have a larger Vₜ difference between threshold voltages V_{t1A}, V_{t1B} than a transistor 110A with a lesser amount of the dopant material in an otherwise same gate insulator 115A. Multiple transistors 110A with different amounts of dopant material in otherwise same gate insulators 115A may have a Vₜ difference between respective threshold voltages V_{t1A} that corresponds to the difference of amounts of the dopant material in gate insulator 115A. In some embodiments, gate insulator 115A includes a dipole dopant at an atomic ratio (e.g., of a dopant second metal to a first metal) of 1:10 or more. In some such embodiments, gate insulator 115A includes the dipole dopant at an atomic ratio (e.g., of the dopant second metal to the first metal) of 2:10 (or 1:5) or less. In these embodiments, gate insulator 115B does not include the dipole dopant (or includes only trace amounts of the dipole dopant, e.g., at an atomic ratio of the dopant second metal to the first metal of less than 1:100; such a measurement may suggest a negligible dopant concentration, below detectable levels). The dopant in gate insulator 115A may be a metal (such as lanthanum, scandium, yttrium, barium, etc.), which may be introduced to gate insulator 115A as part of a metal oxide. In many embodiments, gate insulators 115A, 115B include hafnium and oxygen, and gate insulator 115A additionally includes lanthanum (which gate insulator 115B lacks, e.g., with an atomic ratio of lanthanum to hafnium of less than 1:100). In some such embodiments, the atomic ratio of lanthanum to hafnium in gate insulator 115A is between 1:10 and 1:5.

Gate structures 119 (including gate insulators 115) control the conduction of channel regions 111 and transistors 110, e.g., the conduction between transistor 110 source and drain terminals (not shown). Conduction of channel regions 111 may electrically couple source and drain terminals at opposite ends of channel regions 111 (e.g., in front and behind the viewing planes of FIGS. 1A and 1B, in the positive and negative y directions). In the examples of FIGS. 1A, 1B, channel regions 111 are within fins of doped semiconductor, but in other embodiments, channel regions 111 are within other structures (such as nanoribbons). The structures and included channel regions 111 may be part of a parallel group or array of structures and channel regions 111 (e.g., parallel fins or stacked nanoribbons). For example, parallel channel regions 111 (e.g., with longitudinal axes in the y direction) may be within fins on either side of channel regions 111 and fins shown in FIGS. 1A and 1B. A single, common gate structure 119 may be over multiple channel regions 111.

The doped semiconductor may be any suitable material, such as monocrystalline silicon, and substrate 199 may be the same material. Substrate 199 may include any suitable material or materials. Any suitable semiconductor or other material can be used. Channel regions 111 may be of the same material as substrate 199 or, e.g., be deposited on substrate 199. Substrate 199 may include a semiconductor material that transistors can be formed out of and on, including a crystalline material. Substrate 199 may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon.

Channel regions 111 may include a p-type semiconductor dopant (e.g., electron acceptors, such as boron) or an n-type semiconductor dopant (e.g., electron donors, such as phosphorus or arsenic). Channel regions 111 may couple doped source and drain structures (not shown), which may be more heavily doped and with a different dopant.

In some embodiments, a thin interface layer 112 is over channel region 111, between channel region 111 and gate insulator 115. Optional interface layer 112 may be a passivation layer over channel region 111 and may include a material common to channel region 111, for example, in an oxide. Interface layer 112 may be a conventional or low-K dielectric. In many embodiments, channel region 111 is of silicon, and interface layer 112 is a layer of silicon oxide (e.g., SiO₂).

Gate structure 119 also includes a layer of WFM 113 over gate insulators 115A, 115B. The layer of WFM 113 is conformal over gate insulator 115, which is over the semiconductor fin, channel region 111, and interface layer 112. WFM 113 may be conformal over other gate insulators 115 (and, e.g., fins) within a same transistor 110. WFM 113 may improve (e.g., simplify or make more consistent and/or reliable) the processing of transistors 110.

WFM 113 may (along with fill or bulk metal 114) provide a consistent work function (and Vₜ) reference (e.g., a starting point or baseline), which other structures may then provide work function (or other Vₜ) shifts or adjustments from. For example, all transistors 110 may include identical layers of WFM 113, but some transistors 110 may have other structures and interfaces, e.g., between metals 113, 114 and channel region 111 (such as gate insulator 115) that provide a Vₜ shift from the Vₜ baseline set by metals 113, 114. The identical layers of WFM 113 within all transistors 110 may have equal thicknesses of the same WFM 113. In most embodiments, WFM 113 is an n-WFM. WFM 113 may include multiple elements, both metals (e.g., titanium, tantalum, aluminum, etc.) and nonmetals (e.g., carbon, nitrogen, etc.). In some embodiments, WFM 113 includes titanium and/or aluminum, and carbon. In some embodiments, WFM 113 includes titanium, aluminum, and carbon (e.g., one of titanium or aluminum doped within the other metal in a titanium aluminum carbide).

WFM 113 may also be a barrier metal that provides a liner or container for fill or bulk metal 114. A barrier metal 113 may improve device 100 reliability and stabilize performance by protecting internal layers (e.g., gate insulator 115) from metal 114, for example. WFM 113 may prevent, inhibit, or control the diffusion of metal 114. As a liner or seed layer, metal 113 may provide for the processing of other parts of gate structure 119 (e.g., for the deposition or filling of bulk metal 114).

Bulk metal 114 may be any suitable (e.g., conductive) material. In some embodiments, metal 114 is or includes tungsten. Metal 114 is over WFM 113 and may contribute to the effective work function (and so Vₜ) of gate structure 119. WFM 113, being between metal 114 and channel region 111, may lessen any effect of metal 114 on the work function (and so Vₜ) of gate structure 119.

Insulator 109 over transistor 110 may be an interlayer dielectric (ILD) or intermetal dielectric (IMD), e.g., a low-K dielectric, that provides electrical isolation between a device layer having transistors 110 and layers above (such as interconnect layers). Gate contacts (not shown) through insulator 109 may electrically couple gate structure 119 to an interconnect structure in and through various ILD.

In at least some exemplary embodiments of FIGS. 1A and 1B, transistors 110A, 110B are n-type transistors 110 (e.g., NMOS FETs), gate insulators 115A, 115B include a hafnium oxide (e.g., HfO₂), and gate insulator 115A includes lanthanum at an atomic ratio to hafnium of between 1:10 and 2:10. Gate insulator 115B does not include lanthanum (e.g., insulator 115B includes only undetectable or trace amounts of lanthanum, for example, at an atomic ratio of lanthanum to hafnium of less than 1:100). In at least some of these exemplary embodiments, WFM 113 is an n-WFM 113 of a titanium aluminum carbide, and bulk metal 114 is predominantly tungsten. Transistor 110A has a threshold voltage V_{t1A}, transistor 110B has a threshold voltage V_{t1B}, and threshold voltage V_{t1B} has a greater magnitude than threshold voltage V_{t1A}.

FIG. 1C illustrates transistor 110C on substrate 199 in device 100. Transistor 110C may have a structure similar to that of transistor 110B of FIG. 1B (e.g., with a same or similar gate insulator 115B lacking the dopant material included within gate insulator 115A). Notably, transistor 110C has a layer of WFM 116 over, and in contact with, gate insulator 115B. A layer of WFM 113 is adjacent gate insulator 115B, but over WFM 116, which is between gate insulator 115B and WFM 113. WFM 113, 116 may be of opposite types, which may lessen the effect of WFM 113, for example, by WFM 116 shielding layers and materials internal to WFM 116 from outer layer of WFM 113. For example, in many embodiments, transistors 110 are NMOS transistors, WFM 113 is an n-WFM, and WFM 116 is a p-WFM. In many embodiments, the layer of WFM 116 comprises titanium and nitrogen (e.g., in a titanium nitride, such as TiN). The addition of a titanium nitride layer may have reliability benefits, as titanium nitride is extremely durable and is an excellent barrier metal between the other metals of gate structure 119 (e.g., WFM 113 and bulk metal 114) and gate insulator 115B (and structures internal to insulator 115B, such as channel region 111).

In at least some exemplary embodiments of FIG. 1C, transistor 110C is an n-type transistor 110, and gate insulator 115B (in transistor 110C) includes a hafnium oxide (e.g., HfO₂). Gate insulator 115B does not include lanthanum (e.g., insulator 115B includes only undetectable or trace amounts of lanthanum, for example, at an atomic ratio of lanthanum to hafnium of less than 1:100). In at least one of these exemplary embodiments, WFM 113 is an n-WFM 113 of a titanium aluminum carbide, WFM 116 is a p-WFM 116 of a titanium nitride, and bulk metal 114 is predominantly tungsten. Transistor 110C has a threshold voltage V_{t1C} with a magnitude greater than those of threshold voltages V_{t1A}, V_{t1B}.

FIG. 1D shows transistor 110D on substrate 199 in device 100. Transistor 110D has a gate insulator 115B and may have a structure similar to that of transistor 110C of FIG. 1C (e.g., with a layer of WFM 116 and without the dopant material within gate insulator 115B). Notably, transistor 110D includes WFM 113 adjacent (and WFM layer 116 in contact with) a gate insulator 115B (in transistor 110D), but also with a layer 117 between WFM 113, 116. Layer 117 may be a WFM layer 117 and may provide additional Vₜ tuning external to WFM 116. WFM 116 and layer 117 may be of opposite WFM types, but layer 117 may lessen the effect of WFM 113 (even though WFM 113 and layer 117 may be of the same type), e.g., by layer 117 acting as a spacer and diffusion barrier between WFM 113, 116. For example, in many embodiments, transistors 110 are NMOS transistors, WFM 113 and layer 117 are n-WFM, and WFM 116 is a p-WFM. In many embodiments, layer 117 is a nitride layer 117 (for example, including nitrogen in a compound with a metal, e.g., tantalum in one or more tantalum nitrides, such as TaN). The addition of a tantalum nitride layer may have reliability benefits, as tantalum nitride is a proven diffusion barrier between metals in IC devices.

In at least some exemplary embodiments of FIG. 1D, transistor 110D is an n-type transistor 110, and gate insulator 115B (in transistor 110D) includes a hafnium oxide (e.g., HfO₂). Gate insulator 115B does not include lanthanum (e.g., insulator 115B includes only undetectable or trace amounts of lanthanum, for example, at an atomic ratio of lanthanum to hafnium of less than 1:100). In at least one of these exemplary embodiments, WFM 113 is an n-WFM 113 of a titanium aluminum carbide, WFM 116 is a p-WFM 116 of a titanium nitride, nitride layer 117 is of tantalum nitride (e.g., an n-WFM), and bulk metal 114 is predominantly tungsten. Transistor 110D has a threshold voltage V_{t1D} with a magnitude greater than those of threshold voltages V_{t1A}, V_{t1B}, V_{t1C}.

In some embodiments, device 100 includes all of transistors 110A, 110B, 110C, 110D, which have identical structures and compositions except as illustrated and described (e.g., a dipole dopant in insulator 115A, but absent in insulators 115B), and each of transistors 110A, 110B, 110C, 110D have different threshold voltages V_{t1A}, V_{t1B}, V_{t1C}, V_{t1D}, respectively, in a spread of threshold voltages Vₜ. In some such embodiments, threshold voltage V_{t1D} of transistor 110D has a greater magnitude than threshold voltage V_{t1C} of transistor 110C, threshold voltage V_{t1C} of transistor 110C has a greater magnitude than threshold voltage V_{t1B} of transistor 110B, threshold voltage V_{t1B} of transistor 110B has a greater magnitude than threshold voltage V_{t1A} of transistor 110A.

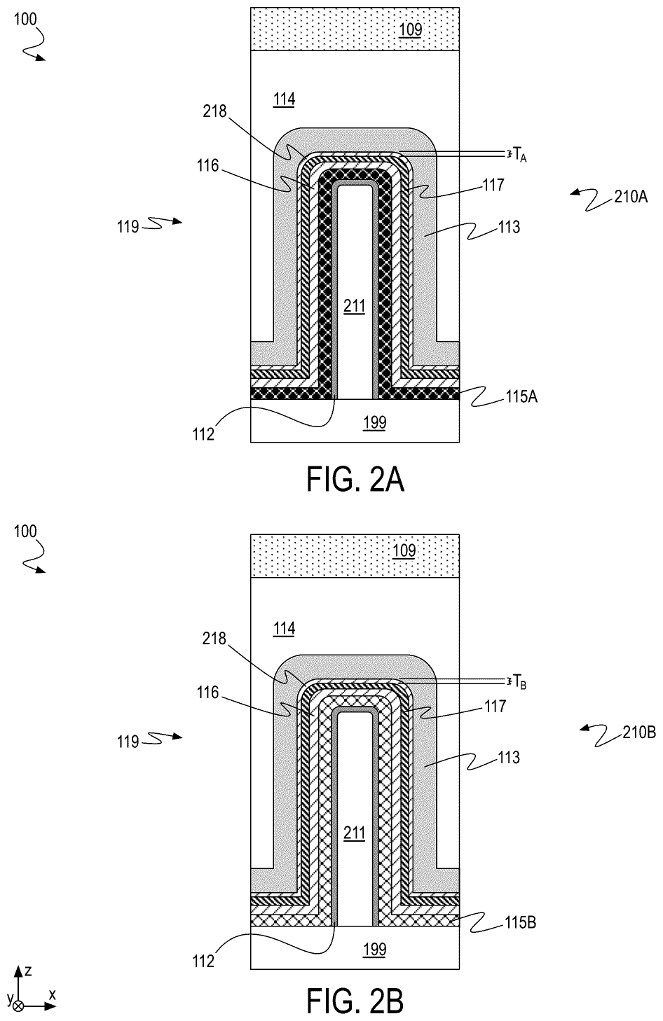

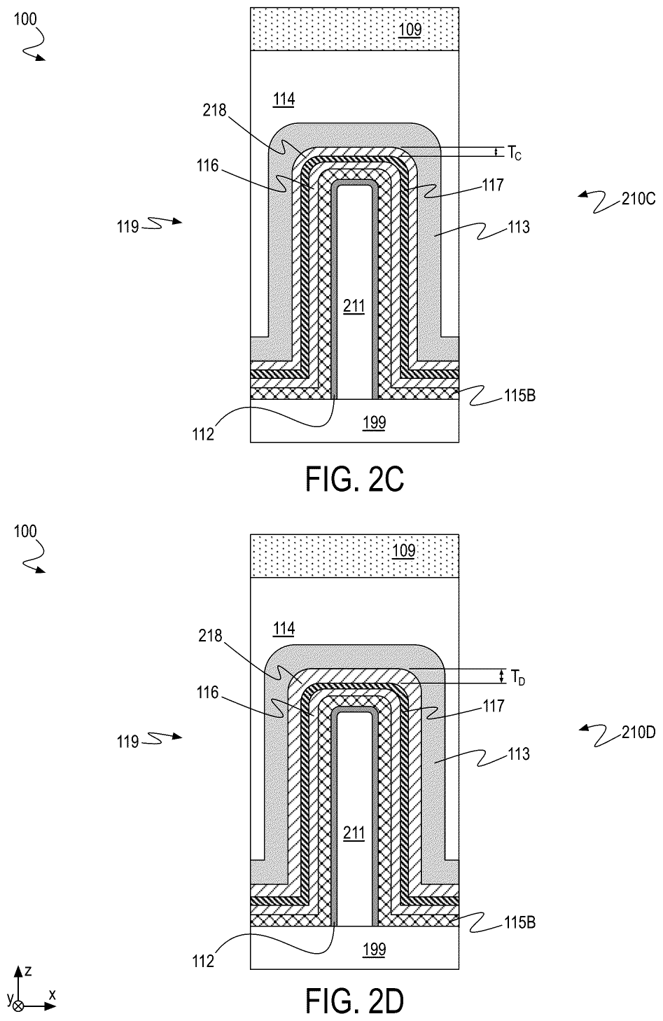

FIGS. 2A, 2B, 2C, and 2D illustrate cross-sectional profile views of transistors 210 with a range of threshold voltages Vₜ in the same IC device 100, in accordance with some embodiments. Transistors 210 may be of a complementary conductivity type to transistors 110 (e.g., described at FIGS. 1A-1D). FIG. 2A shows transistor 210A on substrate 199 in device 100, and FIG. 2B shows transistor 210B also on substrate 199 in device 100. Transistors 210A, 210B have similar structures and each include a gate structure 119 over a semiconductor fin, including a channel region 211 within the fin. Channel region 211 may be similar to, or the same as, channel region 111, except that channel region 211 is of a conductivity type complementary to the conductivity type of channel region 111. For example, channel regions 111, 211 may both be within fin structures of a semiconductor material, such as silicon, but with different (and complementary) dopant materials. One of channel regions 111, 211 may include a p-type or acceptor dopant (such as boron, aluminum, or gallium), and the other of channel regions 111, 211 may include an n-type or donor dopant (such as phosphorous, arsenic, or antimony). Other materials and structures may be employed.

Notably, gate insulators 115 in transistors 210 may be similar to, or the same as, gate insulators 115 in transistors 110. For example, in the embodiments of FIGS. 2A, 2B, transistors 210A, 210B are identical except that (although both gate insulators 115A, 115B include a first metal oxide) insulator 115A in transistor 210A additionally includes a Vₜ-shifting dipole dopant that gate insulator 115B lacks in transistor 210B. In some embodiments, transistors 110A, 210A (and their gate insulators 115A) include the same Vₜ-shifting dipole dopant. In some such embodiments, transistors 110A, 210A and their insulators 115A have the same atomic ratio of the Vₜ-shifting dipole dopant to the first metal. For example, in some embodiments, insulators 115A of transistors 110A, 210A have the same atomic ratio of dopant to hafnium, e.g., between 1:10 and 1:5. Deploying the same dopant may provide benefits, such as reduced processing operations and costs. In other embodiments, transistors 110A, 210A (and their gate insulators 115A) include different Vₜ-shifting dipole dopants, which may provide design flexibility. The use of a single dopant material in FETs of both conductivity types may have complementary effects, e.g., moving threshold voltage Vₜ in a same direction may have opposite effects on magnitudes of threshold voltages Vₜ having opposite polarities.

In many embodiments, transistors 210A, 210B are PMOS transistors (e.g., with negative threshold voltages Vₜ), transistors 110A, 110B are NMOS transistors (e.g., with positive threshold voltages Vₜ), transistors 110B, 210B have gate insulators 115B that include a first metal oxide, and transistors 110A, 210A (and gate insulators 115A) include the first and a second metal (e.g., in an oxide of the second metal). In some such embodiments, n-type transistor 110A has a positive threshold voltage V_{t1A} with a lesser magnitude than positive threshold voltage V_{t1B} of n-type transistor 110B, and p-type transistor 210A has a negative threshold voltage V_{t2A} that is more negative (e.g., with a greater magnitude) than a negative threshold voltage V_{t2B} of p-type transistor 210B. In some such embodiments, all gate insulators 115A, 115B include an oxide of hafnium (e.g., HfO₂), and insulators 115A additionally include lanthanum (e.g., in an oxide of lanthanum). In some embodiments, the second metal included in insulators 115A is scandium, yttrium, or barium. Lanthanum, scandium, yttrium, and barium are examples of Vₜ-shifting n-dipole dopants that shift threshold voltages Vₜ in a negative direction, e.g., reducing a magnitude of a positive threshold voltage Vₜ and increasing a magnitude of a negative threshold voltage Vₜ. Vₜ-shifting p-dipole dopants shift threshold voltages Vₜ in a positive direction. Vₜ-shifting p-dipole dopants may be used to increase a magnitude of a positive threshold voltage Vₜ and reduce a magnitude of a negative threshold voltage Vₜ.

The concentrations of the dipole dopant (e.g., the second metal, such as lanthanum) may be the same, e.g., substantially equal, in insulators 115A in transistors 110A, 210A, which may be an indication of concurrent processing (and a consequent reduction in manufacturing operations). For example, concurrent processing of transistors 110A, 210A may allow for substantially equal concentrations of the dipole dopant in insulators 115A, e.g., by concurrent deposition and then diffusion of equal quantities and concentrations of the dopant. Additionally, if the insulators 115A in transistors 110A, 210A can be processed (e.g., doped) concurrently, these processing operations (e.g., the doping of insulators 115A) need not be repeated for subsequent transistors (e.g., one or more transistors 210A after some processing of one or more transistors 110A is completed). Reduced counts of processing operations correspond to reduced processing times and costs, and increased throughput.

In some embodiments, the concentration of the second metal in insulator 115A in transistor 110A is within 5% of the concentration of the second metal in insulator 115A in transistor 210A. In some embodiments, the concentration of the second metal in insulator 115A in transistor 110A is within 2% of the concentration of the second metal in insulator 115A in transistor 210A. The concentration of the second metal in insulators 115B in transistors 110B, 210B is 0% (e.g., at or below trace or detectable levels). With the concentrations of the dipole dopant (e.g., the second metal) substantially equal in insulators 115A in transistors 110A, 210A, the atomic ratio of a dopant second metal to the first metal in insulator 115A in transistor 210A may be much as described for insulator 115A in transistor 110A. In some embodiments, gate insulator 115A in transistor 210A has an atomic ratio of a dopant second metal to a first metal (e.g., of lanthanum to hafnium) of 1:10 or more. In some such embodiments, gate insulator 115A has an atomic ratio of the dopant second metal to the first metal (e.g., of lanthanum to hafnium) of 2:10 (or 1:5) or less.

Gate structure 119 in transistors 210 may be similar to gate structures 119 in transistors 110. Gate structure 119 includes interface layer 112 over region 211, and gate insulator 115 over layer 112. Gate structure 119 again includes metals 113, 114, with bulk metal 114 over WFM 113. Notably, in the embodiments of FIGS. 2A and 2B, transistors 210 include layer 117 and metal 116, which (while not present in transistors 110 in FIGS. 1A, 1B) may be much as described at FIGS. 1C and/or 1D. Metal 113 is over layer 117. Layer 117 is over metal 116. Metal 116 is over, and in contact with, gate insulators 115A, 115B in transistors 210A, 210B. The views of FIGS. 2A and 2B may show only a portion of gate structures 119. Metals 113, 114, 116 and layer 117 may continue to both sides with conformal layer 117 and metals 113, 116 as liner metals around bulk metal 114. Insulator 109 is over transistor 210A.

Layer 117 and metals 113, 114, 116 may have effects on threshold voltages Vₜ by virtue of their work functions. The magnitudes of these effects and, therefore, the threshold voltages Vₜ may be influenced by the distributions (e.g., volumes) of layer 117 and metals 113, 114, 116, e.g., relative to channel regions 111, 211 and insulators 115. The same layer 117 or metal 113, 114, 116 may have opposite effects on magnitudes of threshold voltages Vₜ in complementary transistors 110, 210, for example, because of opposite polarities of threshold voltages Vₜ in complementary transistors 110, 210.

Transistors 210 additionally include a layer of a metal 218. The layer of a metal 218 is over, and in contact with, layer 117. Layer 117 is over, and in contact with, metal 116 and between metals 116, 218. Metal 218 may be a WFM such that a thickness of metal 218 may affect the values of threshold voltages V_{t2A}, V_{t2B}. In the embodiments of FIGS. 2A, 2B, a thickness TA of the layer of metal 218 in transistor 210A is equal to a thickness T_{B} of the layer of metal 218 in transistor 210B. In many embodiments, the thicknesses and materials in layer 117 and metals 113, 114, 116 are the same in transistors 210A, 210B, and the differences in threshold voltages V_{t2A}, V_{t2B} are due solely to the differing concentrations of the dipole dopant in insulators 115A, 115B. In some embodiments, metal 218 is the same metal as WFM 116. In many embodiments, WFM 218 is of the same type of metal (e.g., a p-type WFM) as WFM 116.

FIGS. 2C and 2D illustrate transistors 210C, 210D on substrate 199 in device 100. Transistors 210C, 210D may have a same or similar structure to that of transistor 210B of FIG. 2B (e.g., with a same or similar gate insulator 115B lacking the dopant material included within gate insulator 115A). Notably, transistor 210C has a thickness T_{C} of the layer of metal 218, transistor 210D has a thickness T_{D} of the layer of metal 218, thickness T_{D} is greater than thickness T_{C}, and thickness T_{C} is greater than thickness T_{B} of metal 218 in transistor 210B. In some embodiments, transistors 210B, 210C, 210D includes the same structures and materials (as shown in FIGS. 2B-2D) with the only differences between transistors 210B, 210C, 210D being that thickness T_{D} is greater than thickness T_{C}, which is greater than thickness T_{B} of metal 218. In at least some such embodiments, a magnitude of threshold voltage V_{t2B} is greater than a magnitude of threshold voltage V_{t2C}, which is greater than a magnitude of threshold voltage V_{t2D}. For example, transistors 210 may be p-type transistors (with negative threshold voltages Vₜ₂) and greater thicknesses T_{C}, T_{D} of a p-WFM 218 correspond to less-negative threshold voltages V_{t2C}, V_{t2D} (e.g., with smaller magnitudes). In other embodiments, a magnitude of threshold voltage V_{t2D} is greater than a magnitude of threshold voltage V_{t2C}, which is greater than a magnitude of threshold voltage V_{t2B}. For example, transistors 210C, 210D may be p-type transistors with greater thicknesses T_{C}, T_{D} of a n-WFM 218, or transistors 210C, 210D may be n-type transistors with greater thicknesses T_{C}, T_{D} of a p-WFM 218. The different threshold voltages V_{t2B}, V_{t2C} V_{t2D} of transistors 210B, 210C, 210D, respectively, may correspond to, and be the result solely of, the different thicknesses T_{B}, T_{C}, T_{D} of metal 218.

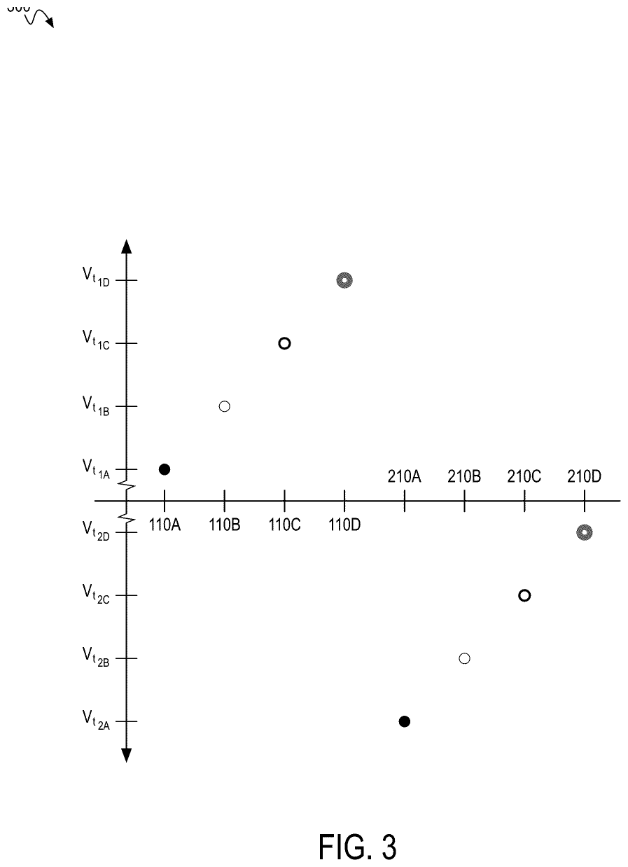

FIG. 3 is a plot showing relative threshold voltages of various transistors 110, 210, in accordance with some embodiments. Each of transistors 110A, 110B, 110C, 110D, 210A, 210B, 210C, 210D occupy discrete positions along the x-axis, whose intersection with the y-axis may not necessarily correspond to threshold voltage Vₜ=0 V. Threshold voltages V_{t1A}, V_{t1B}, V_{t1C}, V_{t1D}, V_{t2A}, V_{t2B}, V_{t2C}, V_{t2D} of transistors 110A, 110B, 110C, 110D, 210A, 210B, 210C, 210D, respectively, are arranged along the y-axis, which is not necessarily drawn to scale. The differences between adjacent threshold voltages Vₜ₁ or Vₜ₂ may be a few millivolts or a few tens of millivolts depending on the differences in WFM volumes and/or gate dielectric dopant concentrations. In some embodiments, transistors 110 are NMOS FETs with positive threshold voltages Vₜ₁, and transistors 210 are PMOS FETs with negative threshold voltages Vₜ₂. In at least some such embodiments, threshold voltage V_{t1D} has a greater magnitude than threshold voltage V_{t1C}, which has a greater magnitude than threshold voltage V_{t1B}, which has a greater magnitude than threshold voltage V_{t1A}. In some yet further such embodiments, threshold voltage V_{t2A} has a greater magnitude than threshold voltage V_{t2B}, which has a greater magnitude than threshold voltage V_{t2C}, which has a greater magnitude than threshold voltage V_{t2D}.

As described at FIGS. 1A, 1B, transistors 110A, 110B may be n-type FETS (with positive threshold voltages Vₜ₁), and a magnitude of threshold voltage V_{t1A} is less than a magnitude of threshold voltage V_{t1B} by virtue of a concentration of n-type dipole dopant in gate insulator 115A greater than a concentration of n-type dipole dopant in gate insulator 115B. As described at least at FIG. 1C, transistor 110C may also be an n-type FET (with positive threshold voltage V_{t1C}), and threshold voltage V_{t1C} may have an increased magnitude greater than a magnitude of threshold voltage V_{t1B} due to the presence of p-type WFM 116 in gate structure 119 of transistor 110C. As described at least at FIG. 1D, transistor 110D may also be an n-type FET (with positive threshold voltage V_{t1D}) with layer 117 between metals 113, 116, and threshold voltage V_{t1D} may have an increased magnitude greater than a magnitude of threshold voltage V_{t1C}.

As described at FIGS. 2A, 2B, transistors 210A, 210B may be p-type FETS (with negative threshold voltages Vₜ₂), and threshold voltage V_{t2A} is more negative (e.g., has a greater magnitude than) threshold voltage V_{t2B} by virtue of a concentration of n-type dipole dopant in gate insulator 115A greater than a concentration of n-type dipole dopant in gate insulator 115B. As described at FIGS. 2C, 2D, transistors 210C, 210D may also be p-type FETS, and threshold voltage V_{t2B} is more negative (e.g., has a greater magnitude) than threshold voltage V_{t2C}, which is more negative (e.g., has a greater magnitude) than threshold voltage V_{t2D}, by virtue of increasing thicknesses of p-WFM 218 (e.g., thickness T_{D} is greater than thickness T_{C}, which is greater than thickness T_{B}).

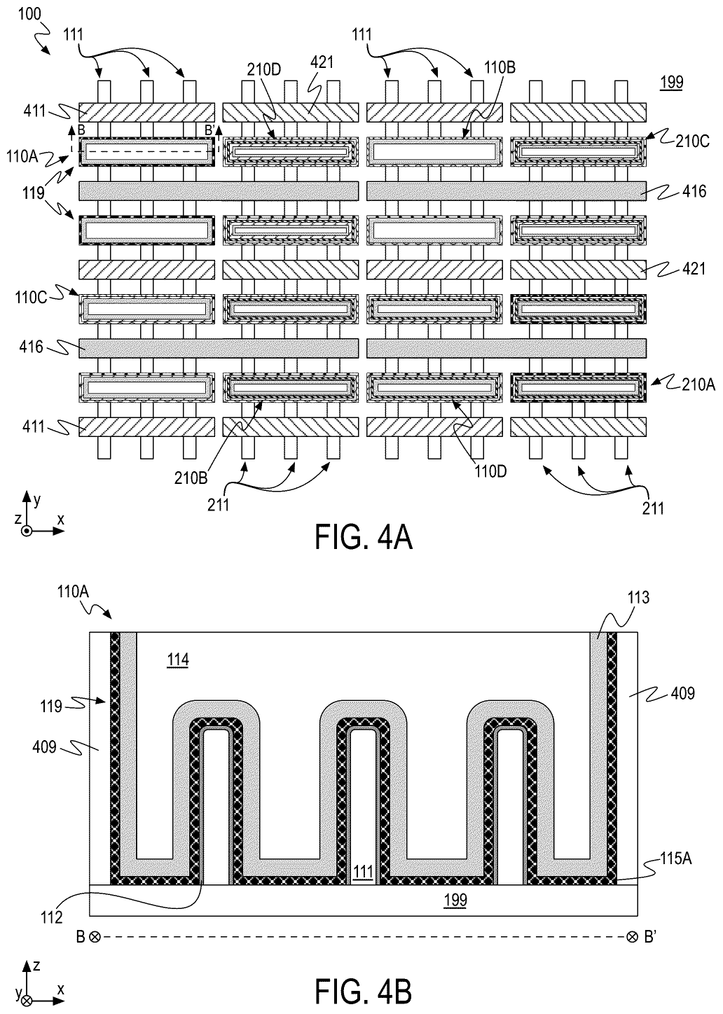

FIGS. 4A and 4B illustrate plan and cross-sectional profile views of an example IC device 100 with transistors 110, 210 of complementary conductivity types in a multi-threshold scheme, in accordance with some embodiments. The plan view of FIG. 4A shows channel regions 111, 211 in fins extending in the y directions. Transistors 110, 210 each include channel regions 111, 211 in three fins. In the example of FIG. 4A, transistors 110 are NMOS FETs, and source contacts 411 are over fins having n-channel regions 111 and are coupled to a positive voltage supply V_{CC}. In the example of FIG. 4A, transistors 210 are PMOS FETs, and source contacts 421 are over fins having p-channel regions 211 and are coupled to a negative (or ground) voltage supply V_{SS}. Drain contacts 416 are shared by transistors 110, 210. Drain contacts 416 are over fins having n- and p-channel regions 111, 211. Contacts 411, 416, 421 may include metallization contacting conductive (e.g., impurity-doped) semiconductor regions in contact with, and on both sides of, channel regions 111, 211. Spacers (not shown) may be insulators between adjacent structures, such as contacts 411, 416, 421 and gate structures 119.

FIG. 4B illustrates a profile view at cross-sectional line B-B′ through gate structure 119 of an example transistor 110A. Transistor 110A includes channel structure 119 over channel region 111 in three fins. Gate insulator 115A is conformal over substrate 199, channel region 111, interface layers 112, and between spacers 409. Spacers 409 are insulators between adjacent structures, e.g., adjacent gate structures 119. Liner metal 113 is conformal in insulator 115A. Fill metal 114 is within liner metal 113.

Returning to FIG. 4A, transistors 110, 210 are deployed in CMOS inverters. When a gate signal on a gate structure 119 causes a transistor 110 to conduct, the shared drain contact 416 is electrically coupled to positive voltage supply V_{CC}. The same gate signal is felt on the (not shown) inverter connection to gate structure 119 of the corresponding transistor 210, which (being of opposite conductivity type and having a threshold voltage Vₜ of opposite polarity) does not conduct. The shared drain contact 416 is not coupled to negative (or ground) voltage supply V_{SS}. When a gate signal on a gate structure 119 causes a transistor 210 to conduct, the shared drain contact 416 is electrically coupled to voltage supply V_{SS}. The same gate signal is felt on the (not shown) inverter connection to gate structure 119 of the corresponding transistor 110, which (being of opposite conductivity type and having a threshold voltage Vₜ of opposite polarity) does not conduct. The shared drain contact 416 is not coupled to voltage supply V_{CC}.

In the example of FIG. 4A, transistors 110, 210 have the threshold voltages Vₜ as shown in FIG. 3. Transistors 110, 210 are strategically paired (e.g., having a shared drain contact 416) in CMOS inverters according to threshold voltage Vₜ. Transistors 110A, 210D have the lowest (magnitude) threshold voltages V_{t1A}, V_{t2D} (and correspondingly faster switching times) and may be deployed in switching paths critical to the high-speed operation of device 100. Transistor 110A includes gate insulator 115A with an n-dipole dopant (as described at least at FIG. 1A). Transistor 210D includes p-WFM 218 with the greatest thickness T_{D} (as described at least at FIG. 2D) and gate insulator 115B without an n-dipole dopant.

Transistors 110D, 210A have the highest (magnitude) threshold voltages V_{t1D}, V_{t2A} (and correspondingly lower leakage currents) and may be deployed in leakage paths critical to saving power in device 100. Transistor 110D includes gate insulator 115B without an n-dipole dopant and with a nitride layer 117 between WFM 113, 116 (as described at least at FIG. 1D). Transistor 210A includes p-WFM 218 with the least thickness TA and includes gate insulator 115A with an n-dipole dopant (as described at least at FIG. 2A).

Transistors 110C, 210B have fairly high (magnitude) threshold voltages V_{t1C}, V_{t2B} (and correspondingly low leakage currents) and may be deployed in leakage paths where saving power in device 100 is somewhat valuable, but not critical, and may be balanced with moderate switching time. Transistor 110C includes WFM 116 between WFM 113 and gate insulator 115B without an n-dipole dopant (as described at least at FIG. 1C). Transistor 210B includes p-WFM 218 with the least thickness T_{B} and includes gate insulator 115B without an n-dipole dopant (as described at least at FIG. 2B).

Transistors 110B, 210C have fairly low (magnitude) threshold voltages V_{t1B}, Vₜ₂ (and correspondingly fast switching times) and may be deployed in switching paths moderately quick operation of device 100 is sufficient and may be balanced with moderate leakage. Transistor 110B includes gate insulator 115B without an n-dipole dopant (as described at least at FIG. 1B) and neither layer 117, nor WFM 116. Transistor 210C includes p-WFM 218 with moderate thickness T_{C} (as described at least at FIG. 2C) and gate insulator 115B without an n-dipole dopant.

Other devices 100 may include transistors 110, 210 in other configurations.

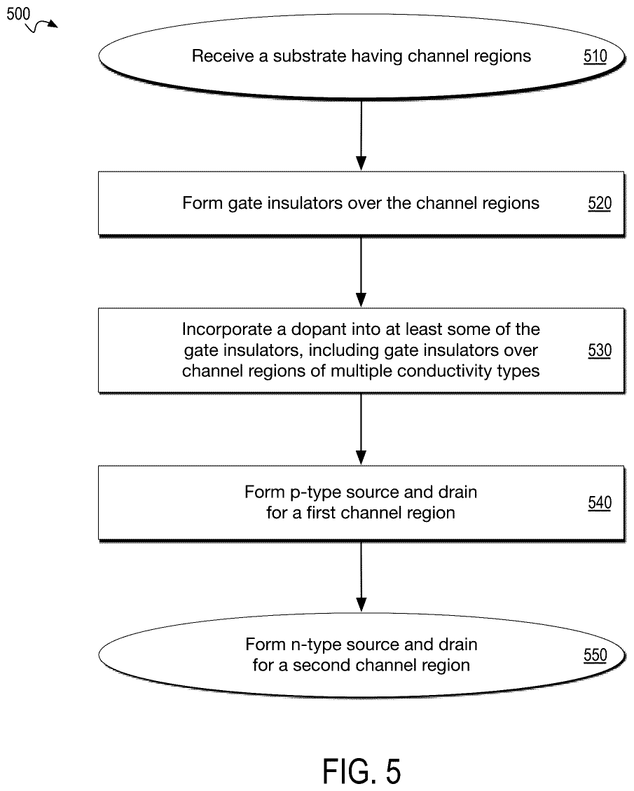

FIG. 5 is a flow chart of methods 500 for forming transistors with multiple threshold voltages, including by doping gate insulators and shifting threshold voltages, in accordance with some embodiments. Methods 500 include operations 510-550. Some operations shown in FIG. 5 are optional. Additional operations may be included. FIG. 5 shows an example sequence, but the operations can be done in other orders as well, and some operations may be omitted. Some operations can also be performed multiple times before other operations are performed. For example, multiple IC dies may be coupled to the device substrate. Some operations may be included within other operations so that the number of operations illustrated FIG. 5 is not a limitation of the methods 500.

Methods 500 begin with receiving a substrate having one or more channel regions, e.g., an IC wafer or die, at operation 510. For example, the substrate may be an IC die or wafer. The channel regions may be in any suitable structure and of any suitable material. In many embodiments, the channel regions are within fins of silicon, but other structures (e.g., nanoribbons) or materials (e.g., other semiconductors) may be employed. The channel regions may be of either or both of p- and/or n-type conductivities. The channel regions may be for transistors with threshold voltages to be shifted by the addition of a dopant to gate insulators over the channel regions, but the substrate may include other channel regions for transistors with threshold voltages that are not to be shifted by a dopant.

Methods 500 continue at operation 520 by forming gate insulators over the channel regions. A gate insulator may include one or more layers of one or more dielectric materials. The one or more materials may be any such material suitable for providing insulation between a channel region and a gate electrode and through which a gate field controls conduction of the channel region. The gate insulator may include a passivation layer over the channel region, such as a native oxide, e.g., an oxide of silicon over a silicon channel region. The gate insulator may include high-K dielectric materials, e.g., metal oxides, which may include oxygen and one or more suitable metals, including hafnium, zirconium, etc. (as described at least at FIGS. 1A, 1B). In many embodiments, the gate insulators include oxygen and either or both of hafnium and zirconium.

The insulators may be formed (e.g., deposited or otherwise grown) by any suitable means. An oxide layer (for example, of a silicon oxide) may be thermally grown and may have nitrogen added to make an oxynitride layer, which may increase a relative permittivity of the layer. Some dielectric layers, such as of metal oxides (e.g., silicates), may be conformally deposited over the channel regions, for example, by chemical vapor deposition (CVD) (e.g., metalorganic CVD (MOCVD) or atomic layer deposition (ALD)).

The gate insulators may be formed (e.g., deposited) over multiple (for example, all) pertinent channel regions concurrently. The same process(es) may be employed for forming gate insulators over either or both of p- and/or n-type channel regions, including gate insulators to be doped and to remain undoped. For example, an oxide of hafnium may be deposited (e.g., by a CVD) over p- and n-type silicon channel regions to be doped, as well as p- and n-type channel regions not to be doped, all simultaneously.

Methods 500 continue with incorporating a dopant into at least some of the gate insulators over the channel regions (e.g., both p- and n-type) at operation 530. Any suitable dopant, such as a dipole dopant, may be deployed. Suitable dopants may shift threshold voltages by altering the permittivity of a gate insulator, e.g., by adjusting a dielectric constant of the insulator. At least some such dopants may have opposite effects in gate insulators over complementary channel regions. For example, an n-dipole dopant may reduce the magnitude of a positive, NMOS transistor threshold voltage, but increase the magnitude of a negative, PMOS transistor threshold voltage. (Although the threshold-voltage shift may be in the same direction, e.g., in the negative direction for an n-dipole dopant, the effect on the magnitude of threshold voltages will be opposite.) In many embodiments, gate insulators over both p- and n-type channel regions are doped with lanthanum (e.g., in an oxide of lanthanum). In other embodiments, gate insulators are doped with at least one of scandium, yttrium, barium, etc. In this way, threshold voltages for p- and n-type channel regions may be shifted by the concurrent incorporation of a single dopant material into gate insulators for both channel-region types.

This concurrent dopant incorporation shifts threshold voltages while reducing the required number of operations in the manufacturing process, saving processing time and costs. By using the same dopant in identical dielectric layers, this concurrent dopant incorporation also reduces process variation by enabling the doping of both NMOS and PMOS gate dielectric to the same (e.g., substantially equal) dopant concentration. Substantially equal dopant concentrations cannot be so readily achieved when using different dielectric layers, dopants, or (even with the same dopant and dielectric layer(s)) doping operations.

The dopant may be incorporated into (and/or through a gate insulator) by any suitable means. In some embodiments, the dopant (e.g., lanthanum in a lanthanum oxide) is deposited on the gate insulators to be doped (e.g., over both p- and n-type channel regions), as well as on the gate insulators to not be doped. In some such embodiments, a mask material (such as a nitride or carbide mask) is deposited over the gate insulators to be doped, and the dopant (e.g., lanthanum) is removed (e.g., wet-etched away) from the gate insulators not to be doped. For example, a block mask may by deposited over n-dipole dopant on n-type transistors with threshold voltages to be shifted down (e.g., lessened in magnitude), and p-type transistors with threshold voltages to be shifted down (e.g., increased in magnitude). Transistors 110A, 210A in FIGS. 1A, 2A may be formed using this process. Dopant can then be removed from all other transistors prior to incorporation into the desired gate insulators. The dopant can be diffused into the desired gate insulators (e.g. insulators 115A) by a drive-in anneal operation. In some embodiments, unincorporated dopant (e.g., lanthanum) is removed from upper surfaces of both gate insulators after such a diffusion, anneal, etc., operation. The masking and concurrent deposition and incorporation of gate insulators (e.g., insulators 115A) saves mask operations and minimizes collateral or parasitic erosion by wet etching, which performance is conserved by a single, concurrent incorporation.

Methods 500 continue at operation 540 by forming a p-type source and drain coupled with one or more p-type channel region(s). Source and drain regions may be impurity-doped semiconductor regions grown (e.g., epitaxially), for example, from an end portion of a channel region otherwise covered (e.g., not the end portions) by a gate insulator (and, for example, any spacers that the gate insulator is between). The end portion may be an exposed end of a fin of, e.g., silicon (or another semiconductor material). Impurity-doped source and drain semiconductor regions may be formed, for example, by growing with a low-pressure CVD (LPCVD) process. The impurity-doped semiconductor regions may include one or more electrically active impurities. For example, the impurity-doped semiconductor may be a Group IV semiconductor material (e.g., Si, Ge, SiGe or GeSn alloy). For exemplary PMOS embodiments, impurity-doped semiconductor regions include a p-type impurity such as boron or aluminum.

Methods 500 continue at operation 550 by forming an n-type source and drain coupled with one or more n-type channel region(s). Source and drain regions may be impurity-doped semiconductor regions grown (e.g., epitaxially), for example, from an end portion of a channel region (such as in a fin) not otherwise covered by a gate insulator, spacers, etc. For exemplary NMOS embodiments, impurity-doped semiconductor regions include an n-type impurity such as phosphorus, arsenic, or antimony.

Processing may continue with further operations, such as contacting and interconnecting transistor terminals.

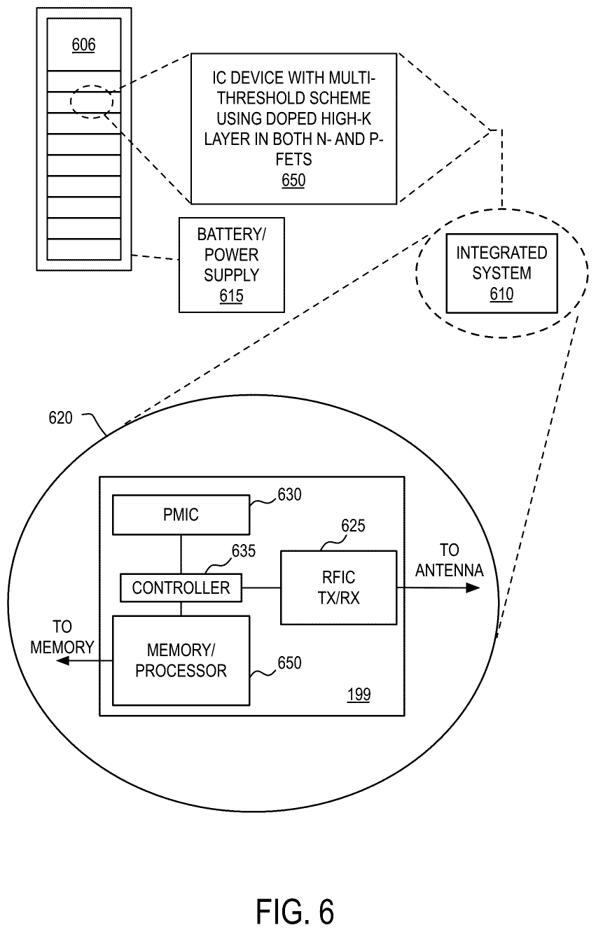

FIG. 6 illustrates a diagram of an example data server machine 606 employing an IC device having both doped gate insulators and multiple threshold voltages in both n- and p-type transistors, in accordance with some embodiments. Server machine 606 may be any commercial server, for example, including any number of high-performance computing platforms disposed within a rack and networked together for electronic data processing, which in the exemplary embodiment includes one or more devices 650 having both n- and p-type transistors with both doped gate insulators and multiple threshold voltages.

Also as shown, server machine 606 includes a battery and/or power supply 615 to provide power to devices 650, and to provide, in some embodiments, power delivery functions, such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having both doped gate insulators and multiple threshold voltages in both n- and p-type transistors, as discussed herein. Device 650 may be further coupled to (e.g., communicatively coupled to) a board, an interposer, or a substrate 199 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include both n- and p-type transistors with both doped gate insulators and multiple threshold voltages.

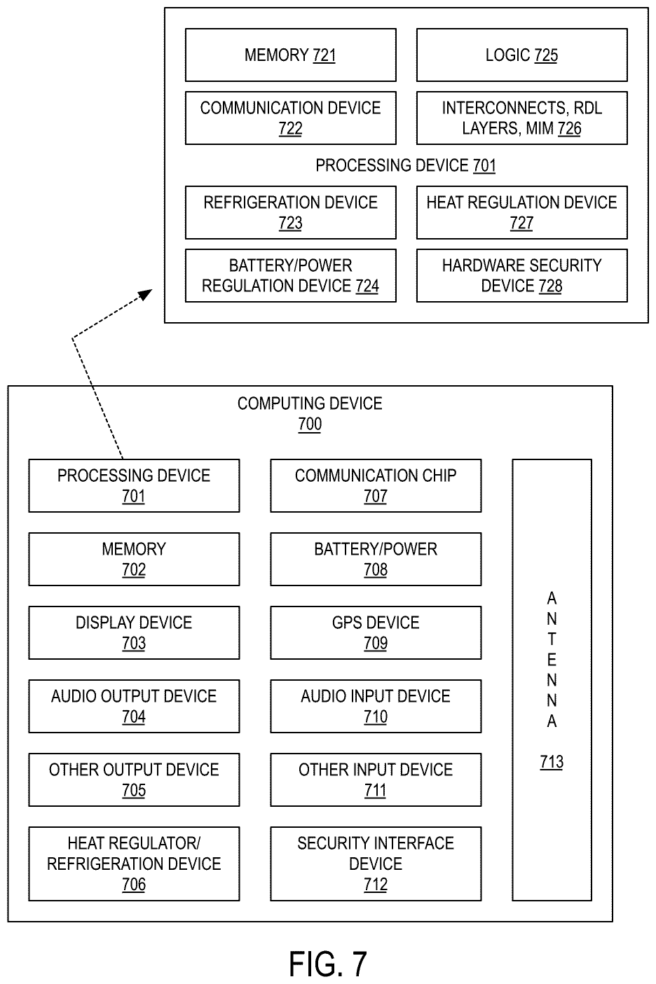

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes n-type first and second transistors including corresponding first and second gate insulators, the first and second gate insulators including oxygen and a first metal, and p-type third and fourth transistors including corresponding third and fourth gate insulators, the third and fourth gate insulators including oxygen and the first metal, wherein the first and third gate insulators include a second metal, and the second metal is lanthanum, scandium, yttrium, or barium.

In one or more second embodiments, further to the first embodiments, a first concentration of the second metal in the first gate insulator is substantially equal to a second concentration of the second metal in the third gate insulator.

In one or more third embodiments, further to the first or second embodiments, the first metal is hafnium, and the second metal is lanthanum.

In one or more fourth embodiments, further to the first through third embodiments, a first atomic ratio of lanthanum to hafnium in the first and third gate insulators is between 1:10 and 2:10, and a second atomic ratio of lanthanum to hafnium in the second and fourth gate insulators is less than 1:100.

In one or more fifth embodiments, further to the first through fourth embodiments, the first transistor has a first threshold voltage, the second transistor has a second threshold voltage, the third transistor has a third threshold voltage, the fourth transistor has a fourth threshold voltage, the second threshold voltage has a greater magnitude than the first threshold voltage, and the third threshold voltage has a greater magnitude than the fourth threshold voltage.

In one or more sixth embodiments, further to the first through fifth embodiments, the third and fourth transistors each include a nitride layer between first and second layers of a p-work function metal, the first layers in contact with the corresponding third and fourth gate insulators, and the second layers over the nitride layers.

In one or more seventh embodiments, further to the first through sixth embodiments, the apparatus also includes a fifth transistor including the nitride layer between the first and second layers, wherein the p-work function metal is in contact with a fifth gate insulator, the fifth gate insulator including oxygen and the first metal, wherein a first thickness of the second layer in the fifth transistor is greater than a second thickness of the second layer in the third or fourth transistor.

In one or more eighth embodiments, further to the first through seventh embodiments, the apparatus also includes a sixth transistor including the nitride layer between the first and second layers, wherein the p-work function metal is in contact with a sixth gate insulator, the sixth gate insulator including oxygen and the first metal, wherein a third thickness of the second layer in the sixth transistor is greater than the first thickness.

In one or more ninth embodiments, further to the first through eighth embodiments, the fourth threshold voltage has a greater magnitude than a fifth threshold voltage of the fifth transistor, and the fifth threshold voltage has a greater magnitude than a sixth threshold voltage of the sixth transistor.

In one or more tenth embodiments, further to the first through ninth embodiments, the apparatus also includes a seventh transistor including an n-work function metal adjacent a seventh gate insulator, and a p-work function metal in contact with the seventh gate insulator, wherein the seventh gate insulator includes oxygen and the first metal.

In one or more eleventh embodiments, further to the first through tenth embodiments, the apparatus also includes an eighth transistor including the n-work function metal adjacent an eighth gate insulator, the p-work function metal in contact with the eighth gate insulator, and a nitride layer between the n- and p-work function metals, wherein the eighth gate insulator includes oxygen and the first metal.

In one or more twelfth embodiments, further to the first through eleventh embodiments, the first transistor has a first threshold voltage, the second transistor has a second threshold voltage, the seventh transistor has a seventh threshold voltage, the eighth transistor has an eighth threshold voltage, the eighth threshold voltage has a greater magnitude than the seventh threshold voltage, and the seventh threshold voltage has a greater magnitude than the second threshold voltage, and the second threshold voltage has a greater magnitude than the first threshold voltage.

In one or more thirteenth embodiments, an apparatus includes an n-type first transistor including an n-work function metal adjacent a first gate insulator, and p-type second, third, and fourth transistors including corresponding second, third, and fourth gate insulators, wherein the first through fourth gate insulators include oxygen and hafnium, the first and second gate insulators further include lanthanum, the second, third, and fourth transistors each include a p-work function metal adjacent the second, third, and fourth gate insulators, wherein a first thickness of a first layer of the p-work function metal in the fourth transistor is greater than a second thickness of a second layer of the p-work function metal in the third transistor, and the second thickness is greater than a third thickness of a third layer of the p-work function metal in the second transistor.

In one or more fourteenth embodiments, further to the thirteenth embodiments, a first concentration of lanthanum in the first gate insulator is substantially equal to a second concentration of lanthanum in the second gate insulator.

In one or more fifteenth embodiments, further to the thirteenth or fourteenth embodiments, the first transistor has positive first threshold voltage, the second transistor has a second threshold voltage with a greater magnitude than a third threshold voltage of the third transistor, and the third threshold voltage has a greater magnitude than a fourth threshold voltage of the fourth transistor.

In one or more sixteenth embodiments, further to the thirteenth through fifteenth embodiments, the apparatus also includes an n-type fifth transistor including a fifth gate insulator including hafnium and oxygen, wherein the fifth transistor has a fifth threshold voltage with a greater magnitude than a first threshold voltage of the first transistor.

In one or more seventeenth embodiments, a method includes receiving a substrate including first and second channel regions, forming corresponding first and second gate insulators over the first and second channel regions, the first and second gate insulators including oxygen and hafnium, incorporating lanthanum into the first and second gate insulators, wherein lanthanum is incorporated into the first gate insulator concurrently with incorporating lanthanum into the second gate insulator, forming a p-type source and drain coupled with the first channel region, and forming an n-type source and drain coupled with the second channel region.

In one or more eighteenth embodiments, further to the seventeenth embodiments, the method also includes removing unincorporated lanthanum from an upper surface of the first or second gate insulator.

In one or more nineteenth embodiments, further to the seventeenth or eighteenth embodiments, the method also includes forming a plurality of third gate insulators over a plurality of third channel regions concurrently with forming the corresponding first and second gate insulators over the first and second channel regions.

In one or more twentieth embodiments, further to the seventeenth through nineteenth embodiments, the method also includes depositing a mask material over the first and second gate insulators prior to incorporating the lanthanum, and removing lanthanum over the plurality of third gate insulators.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
n-type first and second transistors comprising corresponding first and second gate insulators, the first and second gate insulators comprising oxygen and a first metal; and
p-type third and fourth transistors comprising corresponding third and fourth gate insulators, the third and fourth gate insulators comprising oxygen and the first metal, wherein the first and third gate insulators comprise a second metal, and the second metal is lanthanum, scandium, yttrium, or barium.

2. The apparatus of claim 1, wherein a first concentration of the second metal in the first gate insulator is substantially equal to a second concentration of the second metal in the third gate insulator.

3. The apparatus of claim 1, wherein the first metal is hafnium, and the second metal is lanthanum.

4. The apparatus of claim 3, wherein a first atomic ratio of lanthanum to hafnium in the first and third gate insulators is between 1:10 and 2:10, and a second atomic ratio of lanthanum to hafnium in the second and fourth gate insulators is less than 1:100.

5. The apparatus of claim 1, wherein the first transistor has a first threshold voltage, the second transistor has a second threshold voltage, the third transistor has a third threshold voltage, the fourth transistor has a fourth threshold voltage, the second threshold voltage has a greater magnitude than the first threshold voltage, and the third threshold voltage has a greater magnitude than the fourth threshold voltage.

6. The apparatus of claim 5, wherein the third and fourth transistors each comprise a nitride layer between first and second layers of a p-work function metal, the first layers in contact with the corresponding third and fourth gate insulators, and the second layers over the nitride layers.

7. The apparatus of claim 6, further comprising a fifth transistor comprising the nitride layer between the first and second layers, wherein the p-work function metal is in contact with a fifth gate insulator, the fifth gate insulator comprising oxygen and the first metal, wherein a first thickness of the second layer in the fifth transistor is greater than a second thickness of the second layer in the third or fourth transistor.

8. The apparatus of claim 7, further comprising a sixth transistor comprising the nitride layer between the first and second layers, wherein the p-work function metal is in contact with a sixth gate insulator, the sixth gate insulator comprising oxygen and the first metal, wherein a third thickness of the second layer in the sixth transistor is greater than the first thickness.

9. The apparatus of claim 8, wherein the fourth threshold voltage has a greater magnitude than a fifth threshold voltage of the fifth transistor, and the fifth threshold voltage has a greater magnitude than a sixth threshold voltage of the sixth transistor.

10. The apparatus of claim 1, further comprising a seventh transistor comprising an n-work function metal adjacent a seventh gate insulator, and a p-work function metal in contact with the seventh gate insulator, wherein the seventh gate insulator comprises oxygen and the first metal.

11. The apparatus of claim 10, further comprising an eighth transistor comprising the n-work function metal adjacent an eighth gate insulator, the p-work function metal in contact with the eighth gate insulator, and a nitride layer between the n- and p-work function metals, wherein the eighth gate insulator comprises oxygen and the first metal.

12. The apparatus of claim 11, wherein the first transistor has a first threshold voltage, the second transistor has a second threshold voltage, the seventh transistor has a seventh threshold voltage, the eighth transistor has an eighth threshold voltage, the eighth threshold voltage has a greater magnitude than the seventh threshold voltage, and the seventh threshold voltage has a greater magnitude than the second threshold voltage, and the second threshold voltage has a greater magnitude than the first threshold voltage.

13. An apparatus, comprising:
an n-type first transistor comprising an n-work function metal adjacent a first gate insulator; and
p-type second, third, and fourth transistors comprising corresponding second, third, and fourth gate insulators, wherein the first through fourth gate insulators comprise oxygen and hafnium, the first and second gate insulators further comprise lanthanum, the second, third, and fourth transistors each comprise a p-work function metal adjacent the second, third, and fourth gate insulators, wherein a first thickness of a first layer of the p-work function metal in the fourth transistor is greater than a second thickness of a second layer of the p-work function metal in the third transistor, and the second thickness is greater than a third thickness of a third layer of the p-work function metal in the second transistor.

14. The apparatus of claim 13, wherein a first concentration of lanthanum in the first gate insulator is substantially equal to a second concentration of lanthanum in the second gate insulator.

15. The apparatus of claim 13, wherein the first transistor has positive first threshold voltage, the second transistor has a second threshold voltage with a greater magnitude than a third threshold voltage of the third transistor, and the third threshold voltage has a greater magnitude than a fourth threshold voltage of the fourth transistor.

16. The apparatus of claim 13, further comprising an n-type fifth transistor comprising a fifth gate insulator comprising hafnium and oxygen, wherein the fifth transistor has a fifth threshold voltage with a greater magnitude than a first threshold voltage of the first transistor.

17. A method, comprising:
receiving a substrate comprising first and second channel regions;
forming corresponding first and second gate insulators over the first and second channel regions, the first and second gate insulators comprising oxygen and hafnium;
incorporating lanthanum into the first and second gate insulators, wherein lanthanum is incorporated into the first gate insulator concurrently with incorporating lanthanum into the second gate insulator;
forming a p-type source and drain coupled with the first channel region; and
forming an n-type source and drain coupled with the second channel region.

18. The method of claim 17, further comprising removing unincorporated lanthanum from an upper surface of the first or second gate insulator.

19. The method of claim 17, further comprising forming a plurality of third gate insulators over a plurality of third channel regions concurrently with forming the corresponding first and second gate insulators over the first and second channel regions.

20. The method of claim 19, further comprising depositing a mask material over the first and second gate insulators prior to incorporating the lanthanum, and removing lanthanum over the plurality of third gate insulators.
